(19) United States
(12) Patent Application Publication
(10) Pub. No.: US 2025/0372352 A1
(43) Pub. Date: Dec. 4, 2025

(54) REACTION CHAMBER WITH TEMPERATURE CONTROL CAPABILITIES AND SUBSTRATE PROCESSING SYSTEM EQUIPPED WITH THE SAME

(71) Applicant: ASM IP Holding B.V., Almere (NL)

(72) Inventors: Arun Thottappayil, Phoenix, AZ (US); SangBaek Lee, Youngin-si (KR); DaeYoun Kim, Seo-gu (KR); DongRak Jung, Hwaseong-si (KR)

(21) Appl. No.: 19/220,476

(22) Filed: May 28, 2025

Related U.S. Application Data
(60) Provisional application No. 63/654,813, filed on May 31, 2024.

(51) Int. Cl. H01J 37/32; C23C 16/455; C23C 16/48; C23C 16/52

(52) U.S. Cl. CPC H01J 37/32522; C23C 16/45565; C23C 16/48; C23C 16/52; H01J 37/3244; H01J 2237/002; H01J 2237/332

(57) ABSTRACT

A reaction chamber with efficient temperature control capabilities and substrate processing system comprising the reaction chamber is presented. The reaction chamber may comprise a chamber wall configured to encircle a reaction space in which a wafer is processed, a wafer support disposed at a lower part and center of the chamber wall and the wafer support is configured to support the wafer, a showerhead disposed at an upper side of the chamber wall, a gas channel (GC) disposed on and around the showerhead and a temperature control part disposed on the GC and configured to control a temperature of the reaction chamber, wherein a coolant path is disposed in the GC.

### CROSS-REFERENCE TO RELATED APPLICATIONS

This application claims priority to U.S. Provisional Patent Application Ser. No. 63/654,813 filed May 31, 2024 titled REACTION CHAMBER WITH TEMPERATURE CONTROL CAPABILITIES AND SUBSTRATE PROCESSING SYSTEM EQUIPPED WITH THE SAME, the disclosure of which is hereby incorporated by reference in its entirety.

### FIELD OF INVENTION

The present disclosure relates generally to a reaction chamber which processes substrates in semiconductor manufacturing. More particularly, exemplary embodiments of the present disclosure relate to a reaction chamber structure for efficient controlling of temperature of the reaction chamber and a substrate processing system comprises the reaction chambers according to the present disclosure.

### BACKGROUND OF THE DISCLOSURE

Currently, some PEALD chamber reactors may be heated to a specific temperature using heater cartridges. However, in the current reactor structure, which consists of a showerhead, gas channel (GC), and other manifolds, receives additional heat from sources such as radiation from the susceptor and heat from the input RF power (HF & LF).

Due to the reasons above, it is necessary to remove this additional heat to maintain control over the showerhead temperature. The showerhead cartridge heaters should not operate at 0% power. The reactor temperature control should be done by showerhead cartridge heaters.

To achieve this target, a cooling system utilizes process cooling water (PCW) to effectively drain out the excess heat. Also, it is important that the cooling system cannot flow through the showerhead as it is exposed to RF power (RF hot component), which could lead to RF power loss. Additionally, it is crucial to ensure PCW does not boil inside the cooling channel.

Therefore, to achieve the objectives listed above, the present disclosure presents a reaction chamber and a substrate processing system comprising the reaction chambers according to the present embodiment for effective temperature control of the reactors.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment there may be provided, a reaction chamber in a substrate processing system, the chamber comprises: a chamber wall configured to encircle a reaction space in which a wafer is processed; a wafer support disposed at a lower part and center of the chamber wall and the wafer support is configured to support the wafer; a showerhead disposed at an upper side of the chamber wall; a gas channel (GC) disposed on and around the showerhead; and a temperature control part disposed on the GC and configured to control a temperature of the reaction chamber, wherein a coolant path is disposed in the GC.

In an aspect, the temperature control part comprises a thermal contact plate disposed on the GC and configured to adjust thermal contact plate; and a cooling plate part disposed on the thermal contact plate and configured to cool down a heat transferred from the thermal contact plate.

In an aspect, the cooling plate part comprises an upper cooling plate; a lower cooling plate; and a water path disposed in between the upper cooling plate and the lower cooling plate.

In an aspect, wherein the upper cooling plate and the lower cooling plate are bonded with a welding.

In an aspect, wherein the water path is disposed along the thermal contact plate.

In an aspect, wherein both the thermal contact plate's bottom and a surface of GC corresponds to the thermal contact plate's bottom are machined to have n circular sector forms, and the thermal contact plate's bottom and the surface of GC corresponds to the thermal contact plate's bottom are alternately concave and embossed, wherein the n is an even integer bigger than or equal to 4.

In an aspect, wherein the thermal contact plate can be rotated to be oriented with the machined surface of GC for heat removal from the reaction chamber.

In an aspect, wherein the rotation of the thermal contact plate is between a Min value and a Max value.

In an aspect, the Min value is 20% and the Max value is 100%.

In an aspect, wherein the cooling plate part is made of Aluminum (Al).

In an aspect, wherein the thermal contact plate is made of Aluminum nitride (AlN).

In accordance with another embodiment there may be provided, a substrate processing system comprising reaction chambers; a process cooling water (PCW) source; and flow paths between the PCW source and the reaction chambers for cooling temperatures of the reaction chambers, wherein each of the reaction chambers comprises: a chamber wall configured to encircle a reaction space in which a wafer is processed; a wafer support disposed at a lower part and center of the chamber wall and the wafer support is configured to support the wafer; a showerhead disposed at an upper side of the chamber wall; a gas channel (GC) disposed on and around the showerhead; and a temperature control part disposed on the GC and configured to control a temperature of the reaction chamber, wherein a coolant path is disposed in the GC, and the temperature control part comprising: a thermal contact plate disposed on the GC and configured to adjust thermal contact plate; and a cooling plate part disposed on the thermal contact plate and configured to cool down a heat transferred from the thermal contact plate.

In an aspect, each of the reaction chambers further comprising, a coolant inlet disposed on each of the reaction chambers for inputting a PCW from the PCW source into the coolant path; and a coolant outlet disposed on each of the reaction chambers for outputting the PCW from the coolant path into the PCW source.

In an aspect, wherein the flow paths are connected in series from PCW source to the reaction chambers and the PCW source.

In an aspect, wherein the flow paths are connected in parallel between the PCW source and the reaction chambers.

In an aspect, wherein the flow paths are connected in parallel when the PCW in the reaction chambers' coolant paths gets boiled.

In an aspect, the thermal contact plate comprising: a plurality of contact plates configured to adjust thermal contact plate area with the GC, each of the plurality of contact plates is a ‘n-divided circle’ shape, wherein n is an integer bigger than or equal to 4.

In an aspect, wherein each of the plurality of contact plates makes a rotation to be oriented so that the GC and each of the plurality of contact plates makes contact for heat removal from the reaction chamber.

In an aspect, wherein each of the plurality of contact plates' rotation is between a Min value and a Max value.

In an aspect, the Min value is 20% and the Max value is 100%.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 illustrates a general view of a reaction chamber according to an embodiment of the present disclosure.

FIG. 2A illustrates a top-down view of the reaction chamber according to an embodiment of the present disclosure.

FIG. 2B illustrates a view of GC surface which corresponds to the thermal contact plate according to an embodiment of the present disclosure.

FIG. 2C illustrates a perspective view of the cooling plate part according to an embodiment of the present disclosure.

FIG. 2D illustrates GC and the coolant path in the GC according to an embodiment of the present disclosure.

FIG. 3 illustrates thermal contact plate's bottom according to an embodiment of the present disclosure.

FIG. 4 illustrates a coolant inlet tube for providing PCW into the reaction chamber and a coolant outlet tube for draining the PCW from the reaction chamber for controlling the temperature of the reaction chamber according to an embodiment of the present disclosure.

FIG. 5 illustrates a top view a substrate process system comprising 4 reaction chambers according to another embodiment of the present disclosure.

FIG. 6 illustrates a serial connection of the PCW path in a substrate processing system according to another embodiment of the present disclosure.

FIG. 7 illustrates a parallel connection of the PCW path in a substrate processing system according to another embodiment of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

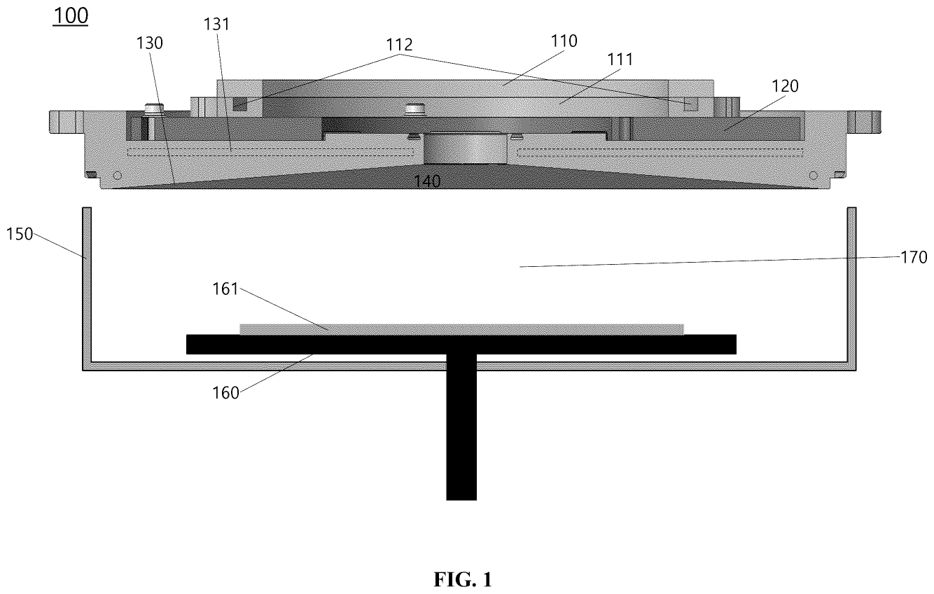

FIG. 1 illustrates a general view of a reaction chamber according to an embodiment of the present disclosure.

The present disclosure's reaction chamber 100 may comprise a chamber wall 150, a wafer support 160 which supports a wafer 161 for processing. The reaction chamber 100 may also comprise a gas channel (GC) 130 and a showerhead 140.

The chamber wall 150 may encircle a reaction space 170 where a wafer is processed and the wafer support 160 may be disposed at a lower part and center of the chamber wall 150. The showerhead 140 may be placed at the upper side of the reaction space and the GC may be disposed on and around the showerhead 140. A coolant path 131 may exist inside of the GC 130.

On top of the GC 130, a temperature control part (110, 111, 120) may be disposed.

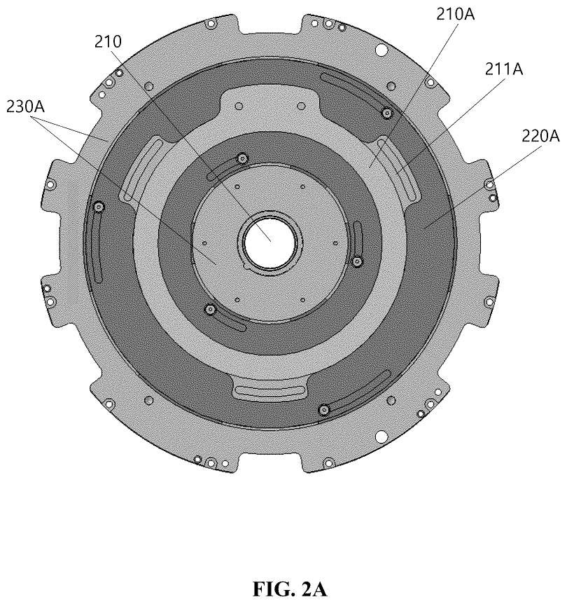

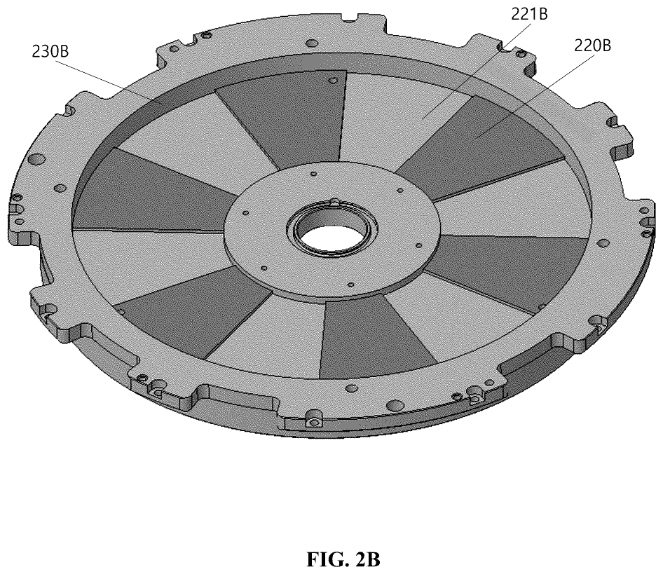

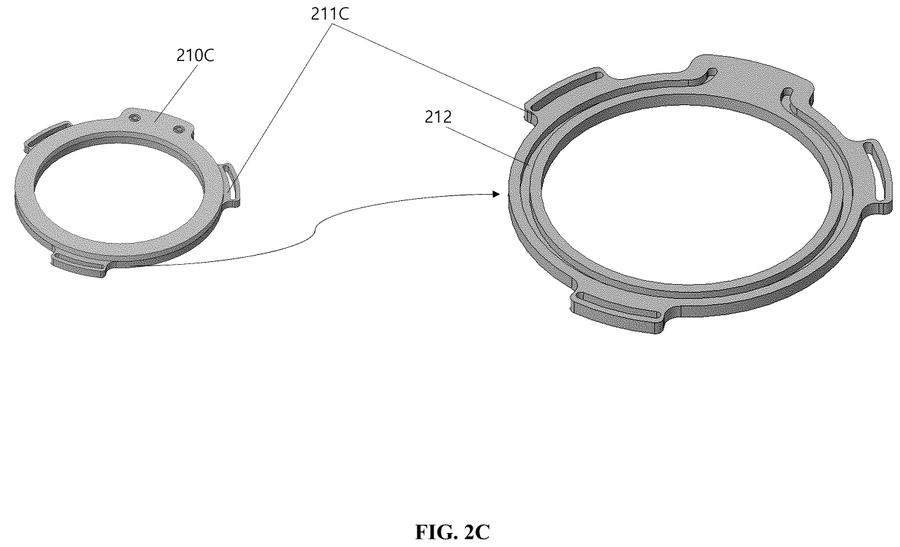

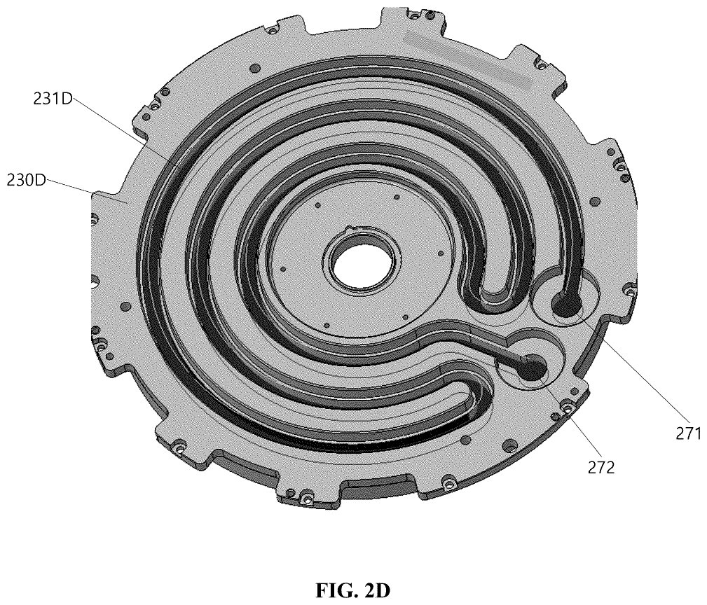

The temperature control part (110, 111, 120) may comprise a cooling plate part 110 and a thermal contact plate 111 and a water path 112 may be placed between the cooling plate part 110 and the thermal contact plate 111. The cooling plate part 110 may be illustrated in FIG. 2C. FIG. 2C illustrates a perspective view of the cooling plate part 110 according to an embodiment of the present disclosure.

The cooling plate part 110 may comprise an upper cooling plate 210C and a lower cooling plate 211C and the upper cooling plate and the lower cooling plate may be welded together. In another embodiment, there may be only 1 cooling plate instead of 2 plates (210C, 211C).

In any case, there may be a water path 212 inside of the space between the upper cooling plate and the lower cooling plate (when 2 plates) or a tube path goes through

(when 1 plate). This water path 212 may be used for cooling down the temperature of the reaction chamber 100 with coolant flowing inside.

FIG. 2A illustrates a top-down view of the reaction chamber according to an embodiment of the present disclosure.

The temperature control part (210A, 211A, 220A) may comprise the cooling plate part (210A, 211A) and the thermal contact plate (220A). Both the cooling plate part (210A, 211A) and the thermal contact plate (220A) may be in the shape of a circle except the center circle area 210 or somewhat bigger center circle area. The GC 230A may be in contact with the temperature control part and this will be explained later.

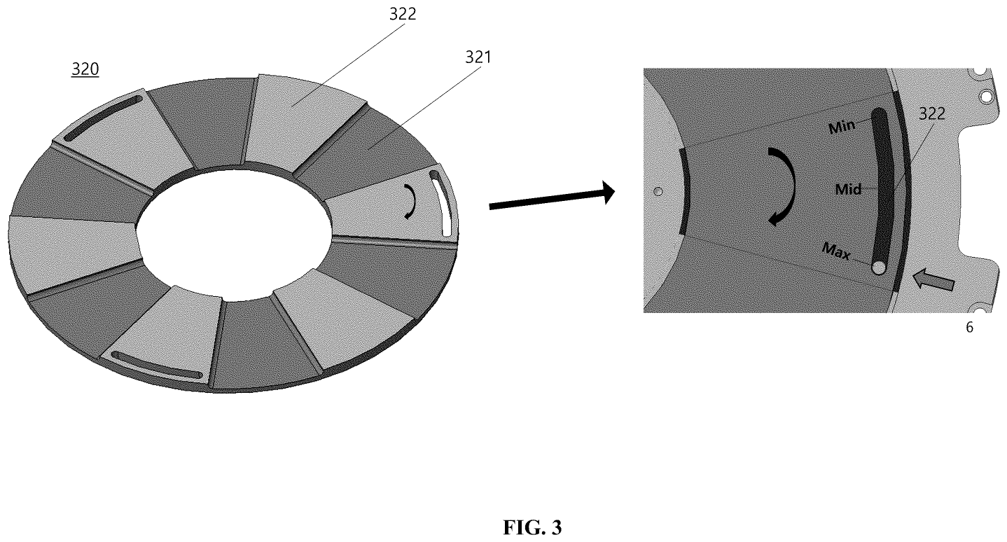

FIG. 2B illustrates a GC surface corresponding to a bottom of the thermal contact plate according to an embodiment of the present disclosure. FIG. 3 illustrates a bottom of thermal contact plate according to an embodiment of the present disclosure. As shown, the surface of GC 230B and the bottom of the thermal contact plate 320 correspond to each other.

The surface of GC 230B and the bottom of the thermal contact plate 320 may be machined to have ‘n’ circular sector forms (except the center circle area), and the n circular sector forms in the thermal contact plate's bottom 320 are alternately concave 321 and embossed 322. Also the n circular sector forms in the surface of GC 230B which corresponds to the thermal contact plate's bottom 320 are alternately concave 221B and embossed 220B.

The concaves and embossed among the n circular sector forms may be alternate therefore n may be an even number and for controlling the contact between GC and thermal contact plate, n may need to be bigger than or equal to 4.

When the GC 230B and thermal contact plate's bottom 320 may be oriented 322, the contact area of GC and thermal contact plate may be changed a heat removal rate from the reaction chamber 100 may be changed. The larger the contact gets, the larger the heat removal rate gets. For better orienting, Max, Mid, Min values may be inscribed to indicate how much contact may be obtained. Usually, Min˜Max is 20%˜100%.

FIG. 2D illustrates GC 230D and the coolant path 231D in the GC according to an embodiment of the present disclosure.

As shown, the coolant path 231D may cover much part of the GC area and a coolant in the coolant path 231D may not go into the showerhead 140. This may prevent any RF power loss from the coolant in the showerhead 140. The coolant path in FIG. 2D (231D) may be the same as the coolant path in FIG. 1 (131). The starting point and end point of the coolant path 231D may be coolant inlet 271/272 and coolant outlet 272/271 for coolant inputting into and outputting from the coolant path 231D for heat removal from the reaction chamber 100.

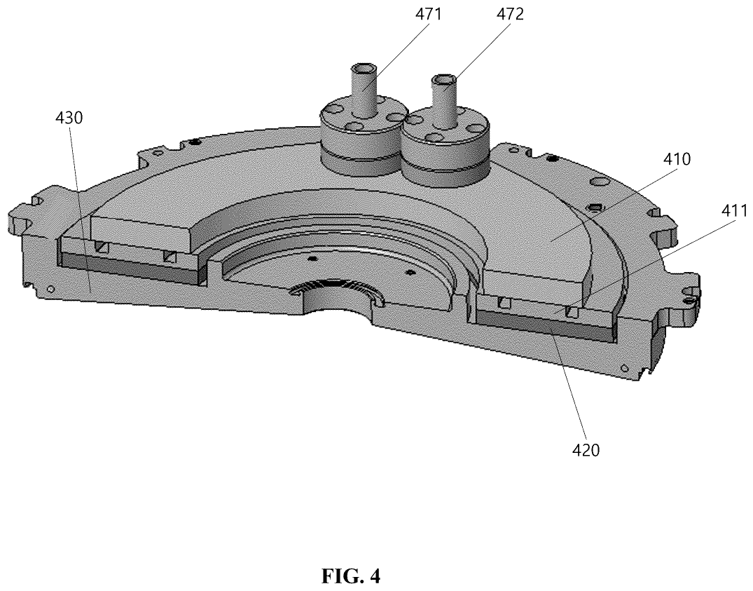

FIG. 4 illustrates a coolant inlet tube 471/472 for providing a process cooling water (PCW) into the reaction chamber and a coolant outlet tube 472/471 for draining the PCW from the reaction chamber for controlling the temperature of the reaction chamber. The coolant provided to the reaction chamber 100 may flow into the water path 212 in the cooling plate part (110, 111) and coolant path 231D in the GC 230D. The upper cooling plate 410 and the lower cooling plate 411 may be used to cool down the heat coming from the coolant in the water path 212 and coolant path 231D and the thermal contact plate 420 may be aligned with the GC 430's surface to control the heat removal rate.

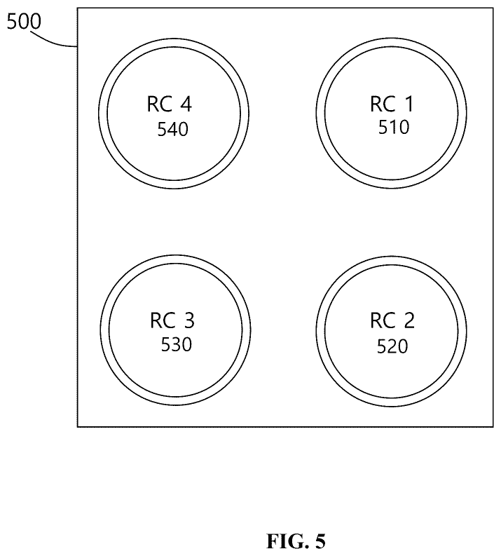

FIG. 5 illustrates a top view a substrate process system comprising 4 reaction chambers according to another embodiment of the present disclosure. Usually, a substrate process system may comprise more than 1 reaction chambers and in this disclosure 4 reaction chambered system is used for example.

A substrate process system 500 may comprise 4 reaction chambers (RCs), i.e., RC1 510, RC2 520, RC3 530, and RC4 540. There may be many ways for cooling down the temperatures of the RCs in FIG. 5.

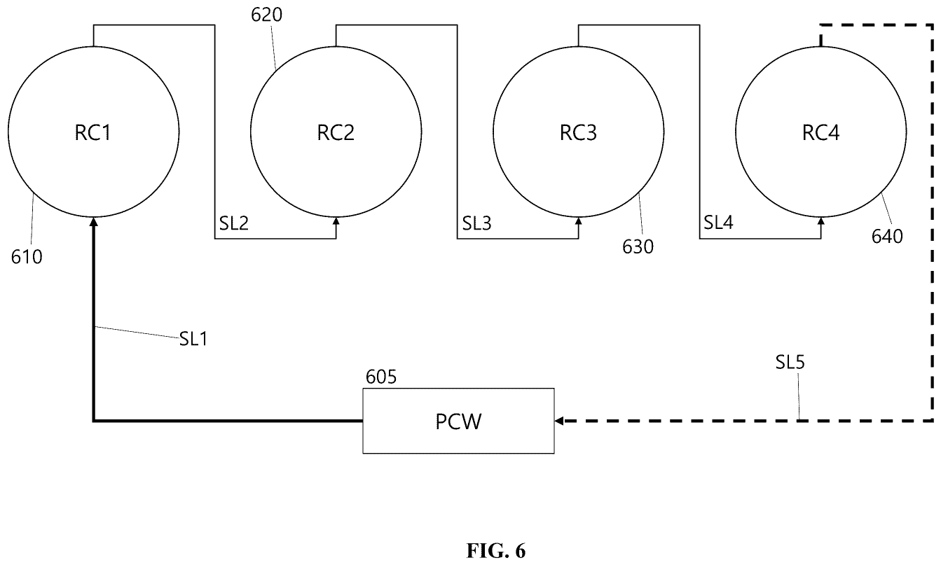

FIG. 6 illustrates a serial connection of the PCW path in a substrate processing system according to another embodiment of the present disclosure.

In this figure, the PCW from the PCW source 605 may move firstly into RC1 610 via SL1 and sequentially into RC2, RC3, RC4 via SL2, SL3 and SL4. Finally, the same PCW returns to the PCW source 605.

Although all RCs may be equipped with the temperature control part (110, 111, 120) therefore cooling down the RC's temperature, the temperature of the PCW may rise once it goes through a new RC. That means, usually temperature (PCW in RC4)>temperature (PCW in RC3)>temperature (PCW in RC2)>temperature (PCW in RC1). And during this PCW circulation, it could happen that the PCW's temperature may rise so much to a point of boiling.

Once PCW boils in the connections of SL1˜SL5 or within the coolant path in each of the RCs, it may no longer function as a coolant.

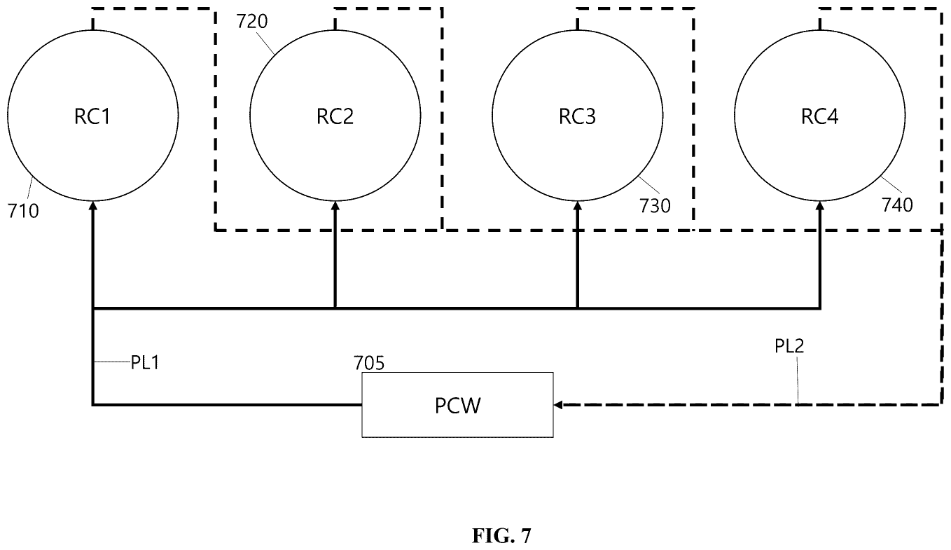

FIG. 7 illustrates a parallel connection of the PCW path in a substrate processing system according to another embodiment of the present disclosure.

The serial connection of PCW circulation in FIG. 6 may cause the boiling of PCW.

Therefore, a parallel connection of PCW circulation may be used.

In this figure, the PCW from the PCW source 705 would be distributed into the RC1 710, RC2 720, RC3 730 and RC4 740 equally via PL1 and the outputs from the RC1˜RC4 may be collected and returned into the PCW source 705 concurrently and in parallel via PL2.

This does not accumulate the heat in the PCW from the previous RC therefore may prevent the PCW from boiling in the connections PL1 and PL2 or in the coolant paths in the RCs.

The above-described arrangements of apparatus are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. A reaction chamber in a substrate processing system, the chamber comprises:
a chamber wall configured to encircle a reaction space in which a wafer is processed;
a wafer support disposed at a lower part and center of the chamber wall and the wafer support is configured to support the wafer;
a showerhead disposed at an upper side of the chamber wall;
a gas channel (GC) disposed on and around the showerhead; and
a temperature control part disposed on the GC and configured to control a temperature of the reaction chamber, wherein a coolant path is disposed in the GC.

2. The chamber according to the claim 1, the temperature control part comprising:
a thermal contact plate disposed on the GC and configured to adjust contact with the GC for thermal control; and
a cooling plate part disposed on the thermal contact plate and configured to cool down a heat transferred from the thermal contact plate.

3. The chamber according to the claim 2, the cooling plate part comprising:
an upper cooling plate;
a lower cooling plate; and
a water path disposed in between the upper cooling plate and the lower cooling plate.

4. The chamber according to the claim 3, wherein the upper cooling plate and the lower cooling plate are bonded with a welding.

5. The chamber according to the claim 3, wherein the water path is disposed along the thermal contact plate.

6. The chamber according to the claim 2, wherein both the thermal contact plate's bottom and a surface of GC corresponds to the thermal contact plate's bottom are machined to have n circular sector forms, and the thermal contact plate's bottom and the surface of GC corresponds to the thermal contact plate's bottom are alternately concave and embossed, wherein the n is an even integer bigger than or equal to 4.

7. The chamber according to the claim 6, wherein the thermal contact plate can be rotated to be oriented with the machined surface of GC for heat removal from the reaction chamber.

8. The chamber according to the claim 7, wherein the rotation of the thermal contact plate is between a Min value and a Max value.

9. The chamber according to the claim 8, the Min value is 20% and the Max value is 100%.

10. The clamber according to the claim 2, wherein the cooling plate part is made of Aluminum (Al).

11. The clamber according to the claim 2, wherein the thermal contact plate is made of Aluminum nitride (AlN).

12. A substrate processing system comprising,
reaction chambers;
a process cooling water (PCW) source; and
flow paths between the PCW source and the reaction chambers for cooling temperatures of the reaction chambers, wherein each of the reaction chambers comprises:
a chamber wall configured to encircle a reaction space in which a wafer is processed;
a wafer support disposed at a lower part and center of the chamber wall and the wafer support is configured to support the wafer;
a showerhead disposed at an upper side of the chamber wall;
a gas channel (GC) disposed on and around the showerhead; and
a temperature control part disposed on the GC and configured to control a temperature of the reaction chamber, wherein a coolant path is disposed in the GC, and the temperature control part comprising:
a thermal contact plate disposed on the GC and configured to adjust contact with the GC for thermal control; and
a cooling plate part disposed on the thermal contact plate and configured to cool down a heat transferred from the thermal contact plate.

13. The substrate processing system according to the claim 12, each of the reaction chambers further comprising,
a coolant inlet disposed on each of the reaction chambers for inputting a PCW from the PCW source into the coolant path; and
a coolant outlet disposed on each of the reaction chambers for outputting the PCW from the coolant path into the PCW source.

14. The system according to the claim 12, wherein the flow paths are connected in series from PCW source to the reaction chambers and the PCW source.

15. The system according to the claim 12, wherein the flow paths are connected in parallel between the PCW source and the reaction chambers.

16. The system according to the claim 15, wherein the flow paths are connected in parallel when the PCW in the reaction chambers' coolant paths gets boiled.

17. The system according to the claim 12, wherein both the thermal contact plate's bottom and a surface of GC corresponds to the thermal contact plate's bottom are machined to have n circular sector forms, and the thermal contact plate's bottom and the surface of GC corresponds to the thermal contact plate's bottom are alternately concave and embossed, wherein the n is an even integer bigger than or equal to 4.

18. The system according to the claim 17, wherein the thermal contact plate can be rotated to be oriented with the machined surface of GC for heat removal from the reaction chamber.

19. The system according to the claim 18, wherein the rotation of the thermal contact plate is between a Min value and a Max value.

20. The system according to the claim 19, the Min value is 20% and the Max value is 100%.
